(19) United States
(12) Patent Application Publication
(10) Pub. No.: US 2025/0096122 A1
(43) Pub. Date: Mar. 20, 2025

(54) VERTICAL ANTIFUSE

(71) Applicant: INTERNATIONAL BUSINESS MACHINES CORPORATION, ARMONK, NY (US)

(72) Inventors: Ashim Dutta, Clifton Park, NY (US); Chih-Chao Yang, Glenmont, NY (US); Oscar van der Straten, Guilderland Center, NY (US); Shravana Kumar Katakam, Lehi, UT (US)

(21) Appl. No.: 18/467,755

(22) Filed: Sep. 15, 2023

(51) Int. Cl. H01L 23/525; H01L 23/522

(52) U.S. Cl. CPC H01L 23/5252; H01L 23/5226

(57) ABSTRACT

A semiconductor structure including a metal sidewall spacer arranged on a vertical sidewall of a dielectric pedestal, a fuse dielectric layer on top of the dielectric pedestal, and a conductive element on top of the fuse dielectric layer and directly above the metal sidewall spacer.

### BACKGROUND

The present invention generally relates to semiconductor structures, and more particularly to a vertical antifuse structure.

Integrated circuit processing can be generally divided into front end of the line (FEOL), middle of the line (MOL) and back end of the line (BEOL) processes. The FEOL and MOL processing will generally form many layers of logical and functional devices. By way of example, the typical FEOL processes include wafer preparation, isolation, well formation, gate patterning, spacer, extension and source/drain implantation, silicide formation, and dual stress liner formation. The MOL generally includes gate and source/drain contacts. Layers of interconnections are formed above these logical and functional layers during the BEOL processing to complete the integrated circuit structure. As such, BEOL processing generally involves the formation of insulators and conductive wiring. The industry has typically used copper as the conductive metal for the interconnect structures most often using a dual damascene process to form a metal line/via interconnect structure.

A fuse is a structure that is normally “on” meaning that current is flowing, but once “programmed” it is “off” meaning that current does not flow. In a fuse, programming means applying a suitable voltage so that the fuse “blows” to create an open circuit or high resistance state. An antifuse is a structure that is normally “off” meaning that no current flows, but once “programmed” it is “on” meaning that current does flow. In an antifuse, programming means applying a suitable voltage to two electrodes and forming a conductive link between them to close the circuit.

In integrated circuitry memory devices, fuses and antifuses can be used for activating redundancy in memory chips and for programming functions and codes in logic chips. Specifically, dynamic random access memory (DRAM) and static random access memory (SRAM) may use fuses and antifuses for such purposes. In addition, fuses and antifuses can also be used to prevent decreased chip yield caused by random defects generated in the manufacturing process. Moreover, fuses and anti-fuses provide for future customization of a standardized chip design. For example, fuses and anti-fuses may provide for a variety of voltage options, packaging pin out options, or any other options desired by the manufacturer to be employed prior to the final processing. These customization possibilities make it easier to use one basic design for several different end products and help increase chip yield.

### SUMMARY

According to an embodiment of the present invention, a vertical antifuse structure is provided. The vertical antifuse structure may include a metal sidewall spacer arranged on a vertical sidewall of a dielectric pedestal, a fuse dielectric layer on top of the dielectric pedestal, and a conductive element on top of the fuse dielectric layer and directly above the metal sidewall spacer.

According to another embodiment of the present invention, a vertical antifuse structure is provided. The vertical antifuse structure may include a metal sidewall spacer arranged on a vertical sidewall of a dielectric pedestal, a conductive element directly above the metal sidewall spacer, and a fuse dielectric layer between and separating the metal sidewall spacer from the conductive element.

According to another embodiment of the present invention, a vertical antifuse structure is provided. The vertical antifuse structure may include a first metal sidewall spacer disposed on a vertical sidewall of a first dielectric pedestal, a first conductive element directly above the first metal sidewall spacer, a second metal sidewall spacer disposed on a vertical sidewall of a second dielectric pedestal, a second conductive element directly above the second metal sidewall spacer, and a fuse dielectric layer, the fuse dielectric layer arranged between and separating the first metal sidewall spacer from the first conductive element, and the fuse dielectric layer arranged between and separating the second metal sidewall spacer from the second conductive element.

### BRIEF DESCRIPTION OF THE DRAWINGS

The following detailed description, given by way of example and not intended to limit the invention solely thereto, will best be appreciated in conjunction with the accompanying drawings, in which:

FIG. 1 illustrates a cross-sectional view of the semiconductor structure during an intermediate step of a method of fabricating an interconnect structure according to an exemplary embodiment;

FIG. 2 illustrates a cross-sectional view of the semiconductor structure after removing portions of the via level according to an exemplary embodiment;

FIG. 3 illustrates a cross-sectional view of the semiconductor structure after forming a conductive layer according to an exemplary embodiment;

FIGS. 4 and 4a, illustrate cross-sectional views of the semiconductor structure after removing portions of the conductive layer to create a metal sidewall spacer according to an exemplary embodiment;

FIG. 5 illustrates a cross-sectional view of the semiconductor structure after forming a third dielectric layer according to an exemplary embodiment;

FIG. 6 illustrates a cross-sectional view of the semiconductor structure after forming a fuse dielectric according to an exemplary embodiment;

FIG. 7 illustrates a cross-sectional view of the semiconductor structure after forming a fourth dielectric layer according to an exemplary embodiment;

FIG. 8 illustrates a cross-sectional view of the semiconductor structure after programming the vertical antifuse structure according to an exemplary embodiment;

FIGS. 9, 10, and 11 illustrate cross-section views of the semiconductor structure depicted in FIG. 7 along section line A-A according to an exemplary embodiment.

FIG. 12 illustrates a cross-sectional view of the semiconductor structure during an intermediate step of a method of fabricating an interconnect structure according to another exemplary embodiment;

FIG. 13 illustrates a cross-sectional view of the semiconductor structure after forming a first pedestal according to an exemplary embodiment;

FIG. 14 illustrates a cross-sectional view of the semiconductor structure after a first conductive layer according to an exemplary embodiment;

FIGS. 15 and 15a, illustrate cross-sectional views of the semiconductor structure after removing portions of the first conductive layer to create a first metal sidewall spacer according to an exemplary embodiment;

FIG. 16 illustrates a cross-sectional view of the semiconductor structure after forming a third dielectric layer according to an exemplary embodiment;

FIG. 17 illustrates a cross-sectional view of the semiconductor structure after forming a fuse dielectric according to an exemplary embodiment;

FIG. 18 illustrates a cross-sectional view of the semiconductor structure after forming a fourth dielectric layer according to an exemplary embodiment;

FIG. 19 illustrates a cross-sectional view of the semiconductor structure after forming a second pedestal according to an exemplary embodiment;

FIG. 20 illustrates a cross-sectional view of the semiconductor structure after forming a second conductive layer according to an exemplary embodiment;

FIGS. 21 and 21a, illustrate cross-sectional views of the semiconductor structure after removing portions of the second conductive layer to create a second metal sidewall spacer according to an exemplary embodiment;

FIG. 22 illustrates a cross-sectional view of the semiconductor structure after forming a fifth dielectric layer according to an exemplary embodiment;

FIG. 23 illustrates a cross-sectional view of the semiconductor structure after forming a sixth dielectric layer according to an exemplary embodiment;

FIG. 24 illustrates a cross-sectional view of the semiconductor structure after programming the vertical antifuse structure according to an exemplary embodiment; and

FIG. 25 illustrates a cross-sectional view of another semiconductor structure according to another exemplary embodiment.

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub-lithographic” may refer to a dimension or size less than current dimensions achievable by photolithographic processes, and the term “lithographic” may refer to a dimension or size equal to or greater than current dimensions achievable by photolithographic processes. The sub-lithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Antifuses become difficult to fabricate when interconnect dimensions scale down. Some antifuse structures can be fabricated by placing metal islands between metal wires embedded in a dielectric material. Other antifuse structures can be fabricated by placing a relatively high resistance metal between metal wires. Such antifuse structures are difficult to fabricate as the spacing between the metal wires becomes sub-15 nm. Additionally, antifuses are typically relatively bulky and take up a valuable space in an integrated circuit design. Further, bulky antifuse structures reduce the amount of available space for more important interconnect structures, for example, metal wires, and other circuit components in the circuit.

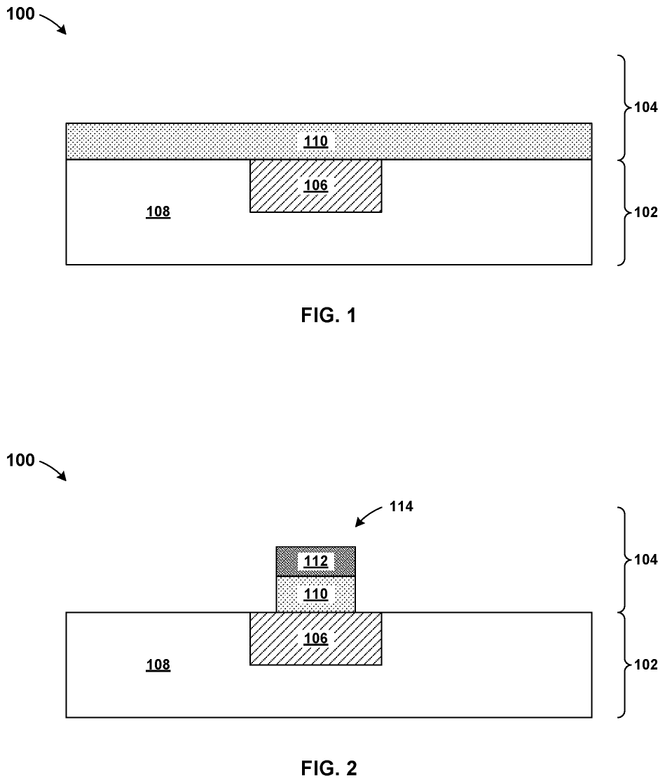

The present invention generally relates to semiconductor structures, and more particularly to a vertical antifuse structure. More specifically, the vertical antifuse structures disclosed herein include two metal sidewall spacers embedded in a dielectric layer above and contacting two metal lines and programming the antifuse structure forms an electrical connection between the two metal sidewall spacers. Exemplary embodiments of antifuse structures are described in detail below by referring to the accompanying drawings in FIGS. 1 to 25. Those skilled in the art will readily appreciate that the detailed description given herein with respect to these figures is for explanatory purposes as the invention extends beyond these limited embodiments.

Referring now to FIG. 1 a demonstrative illustration of a structure 100 is shown during an intermediate step of a method of fabricating a vertical antifuse structure according to an embodiment of the invention.

The structure 100 may include back-end-of-line metallization levels, and more specifically, a metal level 102 and a via level 104. According to at least one embodiment, the via level 104 is above the metal level 102, as illustrated. Although the metallization levels disclosed herein would typically be part of the back-end-of-line, embodiments of the present invention explicitly contemplate other locations and arrangements, such as, for example, middle-of-line, wafer backside, wafer frontside, or other known metallization regions. In all cases, the vertical antifuse structures described herein, and represented by the structure 100, will be integral to the electrical wiring system of a final device or package.

According to at least one embodiment, the metal level 102 is a typical back-end-of-line level and includes a network of conductive lines 106 embedded in a first dielectric layer 108. For purposes of brevity, only a single conductive line 106 is illustrated in the figures of the present embodiment; however, persons having ordinary skill in the art understand the metal level 102 will naturally include multiple conductive lines 106. The conductive lines 106 form the “wiring” or electrical connections to underlying transistors and devices (not shown). The conductive lines 106 may alternatively be referred to as metal lines, traces, or metal traces.

According to embodiments of the present invention, the first dielectric layer 108 may be provided according to known techniques. The first dielectric layer 108 may be made from suitable interlevel dielectric material such as silicon based low-k dielectrics, or porous dielectrics. For example, the first dielectric layer 108 may be made from organic polymer low-k dielectrics and SiCOH-based low-k dielectrics (such as SiCOH, SiCNOH) including selective low-k dielectric deposition.

In an embodiment, the first dielectric layer 108 can be formed using a deposition technique including, for example, chemical vapor deposition (CVD), plasma enhanced chemical vapor deposition (PECVD), physical vapor deposition (PVD), atomic layer deposition (ALD), evaporation, spin-on coating, or sputtering. In some embodiments, a planarization technique such as, for example, chemical mechanical planarization (CMP) and/or grinding is applied after deposition to remove excess material according to known techniques. In other embodiments, no polishing or griding of the first dielectric layer 108 is performed.

According to embodiments of the present invention, the conductive lines 106 may be provided according to known techniques. The conductive lines 106 may include any suitable conductive interconnect materials such as molybdenum, tungsten, rhodium, iridium, copper, or alloys or combinations thereof. In an embodiment, the conductive lines 106 can be formed using conventional damascene techniques in which trenches are formed in the first dielectric layer 108 and subsequently filled with the chosen conductive material. Alternatively, the conductive lines 106 can be subtractivly formed prior to deposition of the first dielectric layer 108.

Like the metal level 102, according to at least one embodiment, the via level 104 is also a typical back-end-of-line level and includes a network of conductive vias, not yet formed, embedded in a second dielectric layer 110. The conductive vias, like the conductive lines 106, also form the “wiring” or electrical connections to underlying transistors and devices. For purposes of the present description, the second dielectric layer 110 is the same, or substantially similar, as the first dielectric layer 108 previously described. In an alternate embodiment, the second dielectric layer 110 is a different material than the first dielectric layer 108.

According to embodiments of the present invention, a height, or thickness, of both the second dielectric layer 110 is generally less than a design height, or thickness, of the via level 104. Furthermore, the height of the via level 104 is equal to a height of any conventional via level. For example, the via level 104 can range from approximately 20 nm to approximately 150 nm; however, other thicknesses are explicitly contemplated. Additionally, according to at least one embodiment, the relative height of the second dielectric layer 110 is approximately 30% to 40% of the total height of the via level 104.

Referring now to FIG. 2, the structure 100 is shown after removing portions of the via level 104 in accordance with an embodiment of the present invention.

An etching technique is applied to generally remove portions of the via level 104 according to known techniques. Specifically, a mask 112 is formed directly on top of the second dielectric layer 110 and exposed portions of the second dielectric layer 110 are removed selective to the mask 112, as shown. A suitable directional etching technique is used to etch exposed portions of the via level 104 and expose topmost surfaces of the first dielectric layer 108 and the conductive lines 106. In all cases, it is critical that topmost surfaces of the conductive lines 106 are exposed during etching, as illustrated. Doing so is critical to the function of the vertical antifuse structures disclosed herein, and which is described in greater detail below.

In some embodiments, the mask 112 may include an oxide such as silicon oxide (SiO), a nitride such as silicon nitride (SiN), an oxynitride such as silicon oxynitride (SiON), combinations thereof, etc. In some embodiments, the mask 112 is a silicon nitride such as Si₃N₄.

The object of this directional etching technique is to form a pedestal 114 generally arranged above the single conductive line 106, as illustrated. Also as illustrated, etching must expose at least portions of the top surfaces of the single conductive line 106. Suitable directional etching techniques may include, but are not limited to: reactive ion etching (RIE), ion beam etching, plasma etching, or laser ablation. In an embodiment, a RIE technique using, for example, with or without including argon ion species, may be used to remove portions of the via level 104, and more specifically to remove portions of the second dielectric layer 110 and the mask 112.

Despite only a single pedestal 114 is illustrated in FIG. 2, embodiments of the present invention explicitly contemplate configurations of the structure 100 which include multiple pedestals 114 arranged above multiple conductive lines 106 respectively. In such embodiments, the pedestals 114 are located or positioned in regions intended for the vertical antifuse structures described herein.

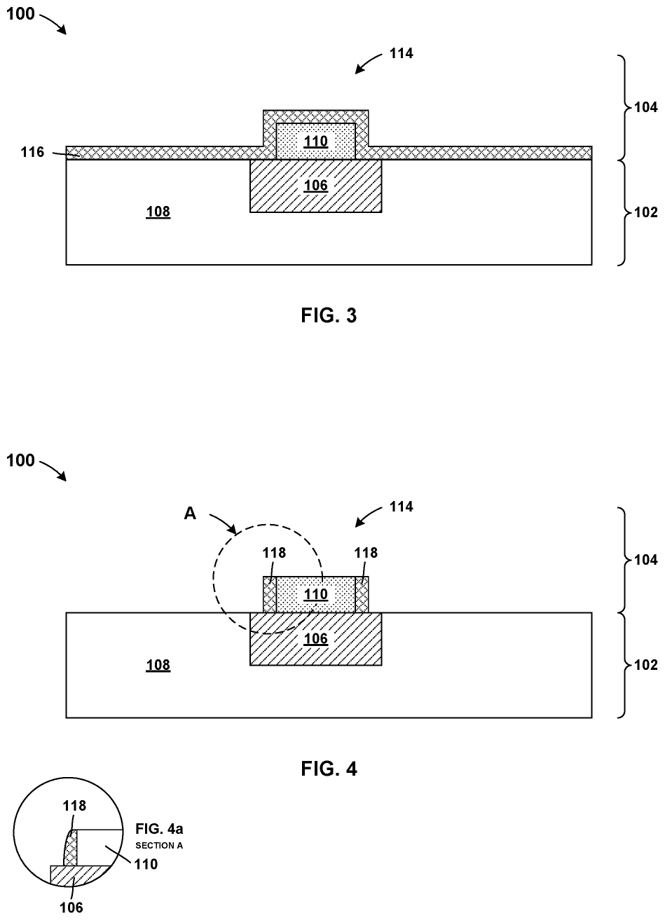

Referring now to FIG. 3, the structure 100 is shown after forming a conductive layer 116 in accordance with an embodiment of the present invention.

After removing the mask 112, the conductive layer 116 is conformally deposited on exposed surfaces of the structure 100 according to known techniques. As used herein, “conformal” it is meant that a material layer has a continuous thickness, or substantially continuous thickness. For example, a continuous thickness generally means a first thickness as measured from a bottom surface to a topmost surface that is the same as a second thickness as measured from an inner sidewall surface to an outer sidewall surface.

According to embodiments of the present invention, the conductive layer 116 may include any suitable conductive material capable of conducting sufficient current of any typical semiconductor circuit having a vertical antifuse structure. In an embodiment, the conductive layer 116 may include tantalum nitride, titanium nitride, ruthenium, tungsten nitride, or some combination thereof. In at least one embodiment, the conductive layer 116 may have a thickness, ranging from about 1 nm to about 10 nm, with 5 nm being most typical. Typically, the conductive layer 116 may include a single layer; however, in other embodiments, it may include multiple layers of different conductive materials.

Since topmost surfaces of the conductive lines 106 are exposed during etching in a prior stage, the conductive layer 116 will directly contact topmost surfaces of the conductive lines 106. It is critical to the function of the vertical antifuse structures described herein.

Referring now to FIGS. 4 and 4a, the structure 100 is shown after removing portions of the conductive layer 116 to create a metal sidewall spacer 118 in accordance with an embodiment of the present invention.

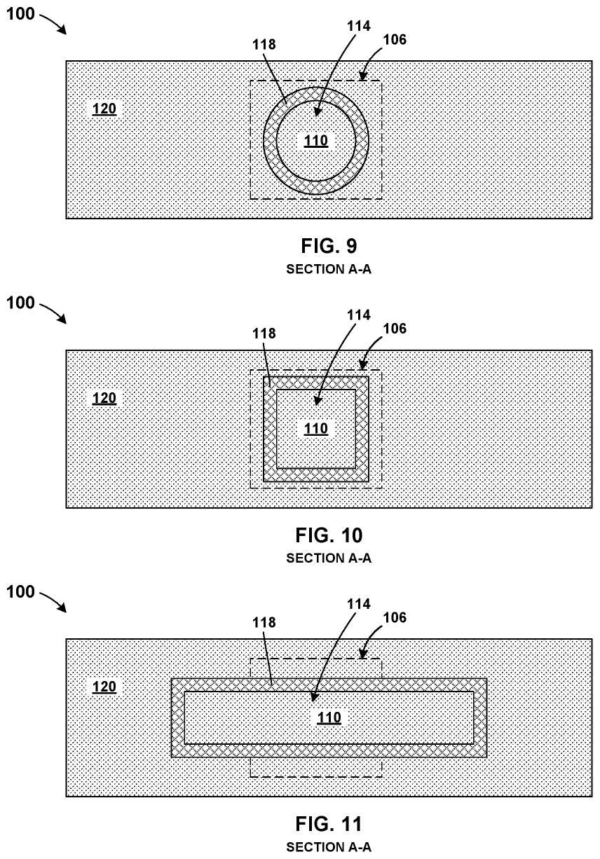

An anisotropic etch is used to remove portions of the conductive layer 116 according to known techniques. Specifically, the anisotropic etch is used to remove portions of the conductive layer 116 from horizontal surfaces of the structure 100 while leaving it on the sidewall of the pedestal 114 and thereby forming the metal sidewall spacer 118. Said differently, after etching the metal sidewall spacer 118 remains on all sides of the pedestal 114 and effectively surrounds the pedestal 114. (See also FIGS. 9, 10, and 11). Although, the metal sidewall spacer 118 does not function as a spacer as is understood persons having ordinary skill in the art, it is referred to as such due the processing techniques used to achieve the metal sidewall spacer 118 mirror those used to create conventional dielectric sidewall spacers. According to all embodiments of the present invention, the metal sidewall spacer 118 may also be referred to generally as a vertical conductor, a fuse conductor, or some combination thereof. More specifically, a bottommost surface of the metal sidewall spacer 118 directly contacts a topmost surface the conductive line 106 and the sidewall of the pedestal 114, as illustrated. In a preferred embodiment, an entirety of the bottommost surface of the metal sidewall spacer 118 directly contacts a topmost surface of the conductive line 106.

In an embodiment, the metal sidewall spacer 118 will be the same conductive material as the conductive layer 116 described above. Also like the conductive layer 116 described above the metal sidewall spacer 118 may have a horizontal or lateral width, or thickness, similar to the thickness of the conductive layer 116; however, etching may reduce the final thickness by about 10% to about 50%. Further, sidewalls of the metal sidewall spacer 118 may have a slightly rounded profile as a result of etching, as illustrated in FIG. 4a.

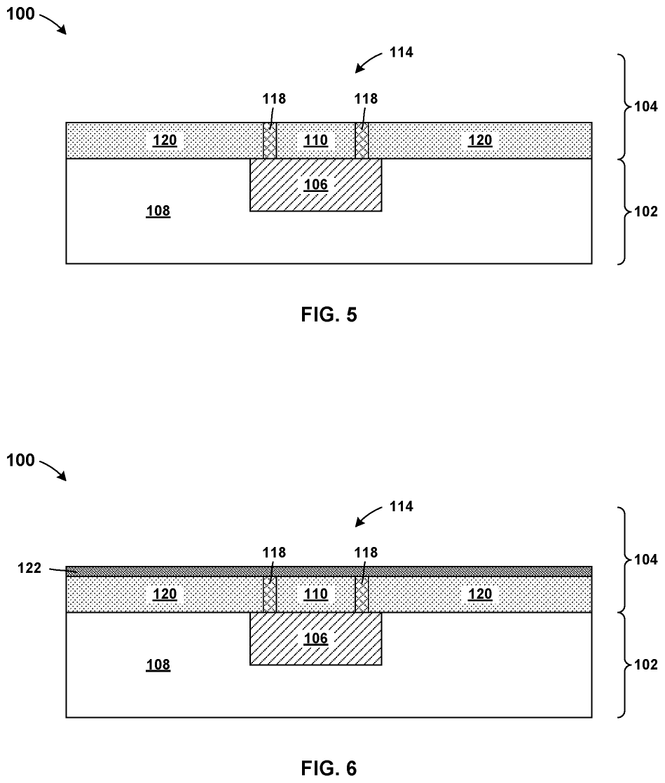

Referring now to FIG. 5, the structure 100 is shown after forming a third dielectric layer 120 in accordance with an embodiment of the present invention.

The third dielectric layer 120 is blanket deposited directly on exposed surfaces of the structure 100 according to known techniques. For purposes of the present description, the third dielectric layer 120 is the same, or substantially similar, as the second dielectric layer 110 previously described. In an alternate embodiment, the third dielectric layer 120 is a different material than the second dielectric layer 110.

After deposition, a planarization technique such as, for example, chemical mechanical planarization (CMP) and/or grinding is applied to remove excess material according to known techniques. After polishing the uppermost surfaces of the third dielectric layer 120 are flush, or substantially flush, with an uppermost surface of the second dielectric layer 110 and the metal sidewall spacer 118.

Referring now to FIG. 6, the structure 100 is shown after forming a fuse dielectric 122 in accordance with an embodiment of the present invention.

The fuse dielectric 122 is blanket deposited directly on exposed surfaces of the structure 100 according to known techniques. It is critical to the present invention that the fuse dielectric 122 is different than either the second dielectric layer 110, the third dielectric layer 120, or both. More specifically, the fuse dielectric 122 is a dielectric material carefully selected for its dielectric breakdown properties. For example, according to embodiments of the present invention, the fuse dielectric 122 has a dielectric breakdown voltage less than the surrounding dielectrics; however, such is not necessary. Alternatively, the fuse dielectric 122 can be chosen based on maximum allowed programming voltage to be used to initiate breakdown. Low dielectric breakdown voltage will help lowering programming voltage.

Dielectric breakdown is the failure of an insulating material to prevent the flow of current under an applied electrical stress. The breakdown voltage is the voltage at which the failure occurs, and the material is no longer electrically insulating.

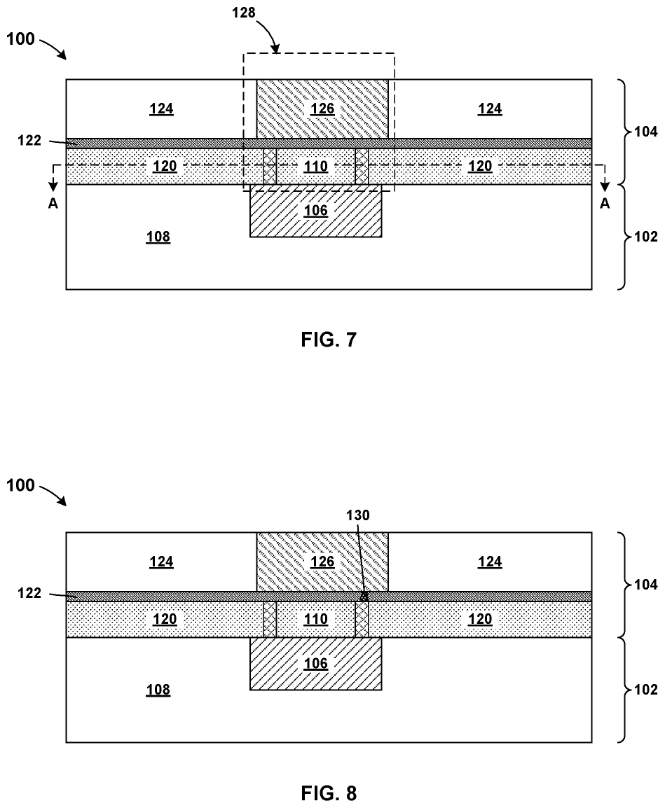

Referring now to FIG. 7, the structure 100 is shown after forming a fourth dielectric layer 124 and a conductive element 126 in accordance with an embodiment of the present invention.

The fourth dielectric layer 124 is blanket deposited directly on exposed surfaces of the structure 100 according to known techniques. For purposes of the present description, the fourth dielectric layer 124 is the same, or substantially similar, as the second dielectric layer 110 and the third dielectric layer 120, previously described. In an alternate embodiment, the fourth dielectric layer 124 is a different material than the second dielectric layer 110, the third dielectric layer 120, or both.

Next, the conductive element 126 is formed in the fourth dielectric layer 124 according to known techniques. For example, according to typical damascene techniques, a trench is formed in the fourth dielectric layer 124 and then subsequently filled with a conductive material thereby forming the conductive element 126. According to disclosed embodiments, the conductive element 126 can be a metal line or via. Additionally, the vertical antifuse structure, made of the metal sidewall spacer 118 and the conductive element 126, is arranged in the via level 104 and functions to provide electrical connections between two successive metal levels, one being the metal level 102. As such, a cumulative height, or thickness, of the metal sidewall spacer 118, the fuse dielectric 122, and the conductive element 126 is generally equal to a design height, or thickness, of the via level 104.

After deposition, a planarization technique such as, for example, chemical mechanical planarization (CMP) and/or grinding is applied to remove excess material according to known techniques. After polishing topmost surfaces of the fourth dielectric layer 124 are flush, or substantially flush, with a topmost surface of the conductive element 126, as illustrated.

Finally, for purposes of the present description the metal sidewall spacer 118, the fuse dielectric 122, and the conductive element 126 together form a vertical antifuse structure 128. Further, embodiments disclosed herein explicitly contemplate multiple vertical antifuse structures 128.

Referring now to FIG. 8, the structure 100 is shown after programming the vertical antifuse structure 128 in accordance with an embodiment of the present invention.

The relatively small distance between the metal sidewall spacer 118 and the conductive element 126, coupled with the existence of the fuse dielectric 122 together create a “weak point” prone to dielectric breakdown. More specifically, dielectric breakdown during fuse programing creates a conductive link 130 between the metal sidewall spacer 118 and the conductive element 126, as illustrated. The vertical antifuse structure 128 can be programmed by applying a programming voltage to one of the metal sidewall spacer 118 or the conductive element 126 and grounding the other. In the context of the present invention, either the programming voltage or the ground may be applied to either of the metal sidewall spacer 118 or the conductive element 126, and vice versa. According to the illustrated embodiment, the programming voltage and/or the ground may be applied to the metal sidewall spacer 118 via the conductive line 106. Persons having ordinary skill in the art understand the structure 100 disclosed herein will be part of a larger integrated circuit and include additional metal layers, wiring, traces, vias which may also be involved in programming.

The programming voltage, which should be equal to or greater than the breakdown voltage of the fuse dielectric 122 may range from about 1 V to about 10 V, and have a current ranging from about 2 mA to about 10 mA. As a result, the fuse dielectric 122 no longer serves as an insulator, and conductive paths, for example the conductive link 126, are created within the fuse dielectric 122 between the metal sidewall spacers 118, as illustrated.

Although not critical, the conductive link 130 may have a lateral width or thickness ranging from about 1 nm to about 10 nm and ranges there between. The length of the conductive link 130 is approximately equal to a relative thickness of the fuse dielectric 122. In the present embodiments, the breakdown distance, or thickness of the fuse dielectric 122, is substantially equal to a vertical distance between the topmost surface of the metal sidewall spacer 118 and the bottommost surface of the conductive element 126. Both the thickness of the fuse dielectric 122 and the fuse dielectric 122 will affect how much programming current is required and how long it takes to program the vertical antifuse structure 128 or form the conductive link 130.

With continued reference to FIG. 8, although only a single conductive link 130 is depicted in the figures, programming may result in multiple conductive links 130 of varying sizes. Additionally, the one or more conductive links 130 may form anywhere along the topmost surface of the metal sidewall spacer 118. As previously mentioned, programming of the vertical antifuse structure 128 is primarily dependent on the thickness of the fuse dielectric 122 and the material of the fuse dielectric 122; however, the lateral thickness of the metal sidewall spacer 118 can also affect programing.

As illustrated in FIGS. 7 and 8, the vertical antifuse fuse structure 128 has some distinctive and notable features. For example, the vertical antifuse fuse structure 128 has a smaller footprint than typical antifuse structures and can thus be implemented in higher density arrangements. Additionally, the fuse-area, or region where the conductive 130 link forms, is relatively small and very localized which offers increased programming control with lower programing voltages. Specific to the embodiments disclosed herein, the fuse-area of the antifuse structure 262, described below with reference to FIG. 23 is more localized than the fuse-area of the structure 100.

With continued reference to FIGS. 7 and 8, according to an embodiment the fuse structures represented by the structure 100 includes a metal sidewall spacer arranged on a vertical sidewall of a dielectric pedestal, a fuse dielectric layer on top of the dielectric pedestal, and a conductive element on top of the fuse dielectric layer and directly above the metal sidewall spacer.

With continued reference to FIGS. 7 and 8, according to an embodiment, the fuse structures represented by the structure 100 further includes a conductive line immediately below and directly contacting a bottommost surface of the metal sidewall spacer.

With continued reference to FIGS. 7 and 8, according to an embodiment, an entirety of a bottommost surface of the metal sidewall spacer directly contacts a topmost surface of the conductive line.

With continued reference to FIGS. 7 and 8, according to an embodiment, the metal sidewall spacer surrounds the dielectric pedestal on all sides.

With continued reference to FIGS. 7 and 8, according to an embodiment, a vertical distance between a topmost surface of the metal sidewall spacer and a bottommost surface of the conductive element is equal to a thickness of the fuse dielectric layer.

With continued reference to FIGS. 7 and 8, according to an embodiment, the conductive element further comprises another metal sidewall spacer surrounding another dielectric pedestal, wherein a topmost surface of the fuse dielectric layer directly contacts a bottommost surface of the another metal sidewall spacer.

With continued reference to FIGS. 7 and 8, according to an embodiment, the fuse structures represented by the structure 100 further includes a conductive link in direct contact with and extending between a topmost surface of the metal sidewall spacer and a bottommost surface of the conductive element through the fuse dielectric layer.

With continued reference to FIGS. 7 and 8, according to an embodiment the fuse structures represented by the structure 100 includes a metal sidewall spacer arranged on a vertical sidewall of a dielectric pedestal, a conductive element directly above the metal sidewall spacer, and a fuse dielectric layer between and separating the metal sidewall spacer from the conductive element.

With continued reference to FIGS. 7 and 8, according to an embodiment the fuse structures represented by the structure 100 includes a first metal sidewall spacer disposed on a vertical sidewall of a first dielectric pedestal, a first conductive element directly above the first metal sidewall spacer, a second metal sidewall spacer disposed on a vertical sidewall of a second dielectric pedestal, a second conductive element directly above the second metal sidewall spacer, and a fuse dielectric layer, the fuse dielectric layer arranged between and separating the first metal sidewall spacer from the first conductive element, and the fuse dielectric layer arranged between and separating the second metal sidewall spacer from the second conductive element.

Referring now to FIGS. 9,10, and 11, depict cross-sectional views of the structure 100 according to alternative embodiment of the invention. Specifically, FIGS. 9, 10, and 11 each depict a cross-sectional view of the structure 100 shown in FIG. 7 taken along line A-A. The embodiments depicted in FIGS. 9, 10, and 11 illustrate different configurations of the metal sidewall spacer 118. In at least one embodiment, the metal sidewall spacer 118 depicted in FIG. 9 has a relatively round, circular, or cylindrical shape. In another embodiment, the metal sidewall spacer 118 depicted in FIG. 10 has a relatively square shape. In another embodiment, the metal sidewall spacer 118 depicted in FIG. 10 has a relatively rectangular shape. In all cases, the relative shape of the metal sidewall spacer 118 corresponds the relative shape of the pedestal 114. In most cases, it is preferred that an entirety of a bottommost surface of the metal sidewall spacer 118 directly contacts a topmost surface of the conductive line 106, as illustrated in FIGS. 9 and 10; however, such is not critical nor required. For example, the metal sidewall spacer 118 of FIG. 11 has a larger footprint than the underlying conductive line 106, and thus only a portion of a bottommost surface of the metal sidewall spacer 118 directly contacts a topmost surface of the conductive line 106.

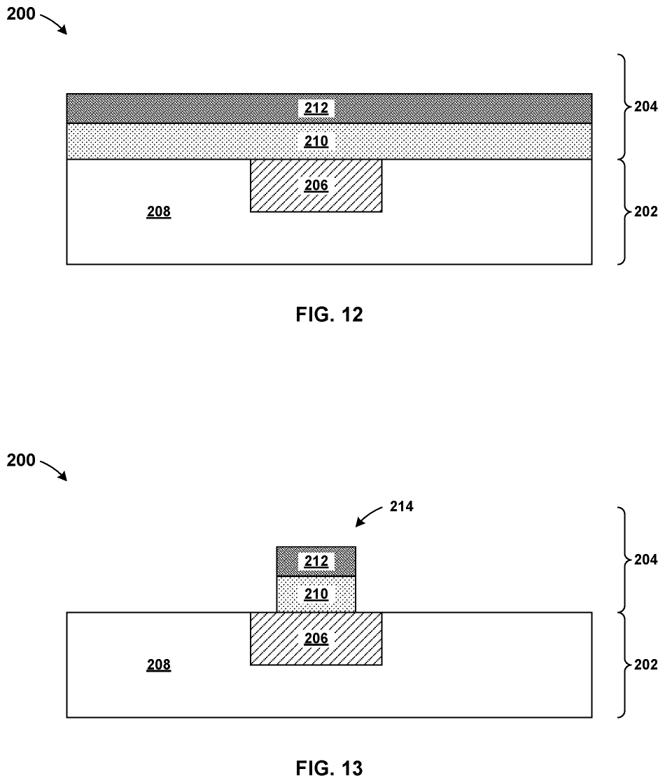

Referring now to FIG. 12 a demonstrative illustration of a structure 200 is shown during an intermediate step of a method of fabricating a vertical antifuse structure according to an alternative embodiment of the invention.

The structure 200 may include back-end-of-line metallization levels, and more specifically, a metal level 202 and a via level 204. According to at least one embodiment, the via level 204 is above the metal level 202, as illustrated. Although the metallization levels disclosed herein would typically be part of the back-end-of-line, embodiments of the present invention explicitly contemplate other locations and arrangements, such as, for example, middle-of-line, wafer backside, wafer frontside, or other known metallization regions. In all cases, the vertical antifuse structures described herein, and represented by the structure 200, will be integral to the electrical wiring system of a final device or package.

According to at least one embodiment, the metal level 202 is a typical back-end-of-line level and includes a network of conductive lines 206 embedded in a first dielectric layer 208. For purposes of brevity, only a single conductive line 206 is illustrated in the figures of the present embodiment; however, persons having ordinary skill in the art understand the metal level 202 will naturally include multiple conductive lines 206. The conductive lines 206 form the “wiring” or electrical connections to underlying transistors and devices (not shown). The conductive lines 206 may alternatively be referred to as metal lines, traces, or metal traces.

According to embodiments of the present invention, the first dielectric layer 208 may be provided according to known techniques. The first dielectric layer 208 may be made from suitable interlevel dielectric material such as silicon based low-k dielectrics, or porous dielectrics. For example, the first dielectric layer 208 may be made from organic polymer low-k dielectrics and SiCOH-based low-k dielectrics (such as SiCOH, SiCNOH) including selective low-k dielectric deposition.

In an embodiment, the first dielectric layer 208 can be formed using a deposition technique including, for example, chemical vapor deposition (CVD), plasma enhanced chemical vapor deposition (PECVD), physical vapor deposition (PVD), atomic layer deposition (ALD), evaporation, spin-on coating, or sputtering. In some embodiments, a planarization technique such as, for example, chemical mechanical planarization (CMP) and/or grinding is applied after deposition to remove excess material according to known techniques. In other embodiments, no polishing or griding of the first dielectric layer 208 is performed.

According to embodiments of the present invention, the conductive lines 206 may be provided according to known techniques. The conductive lines 206 may include any suitable conductive interconnect materials such as molybdenum, tungsten, rhodium, iridium, copper, or alloys or combinations thereof. In an embodiment, the conductive lines 206 can be formed using conventional damascene techniques in which trenches are formed in the first dielectric layer 208 and subsequently filled with the chosen conductive material. Alternatively, the conductive lines 206 can be subtractivly formed prior to deposition of the first dielectric layer 208.

Like the metal level 202, according to at least one embodiment, the via level 204 is also a typical back-end-of-line level and includes a network of conductive vias, not yet formed, embedded in a second dielectric layer 210. The conductive vias, like the conductive lines 206, also form the “wiring” or electrical connections to underlying transistors and devices. For purposes of the present description, the second dielectric layer 210 is the same, or substantially similar, as the first dielectric layer 208 previously described. In an alternate embodiment, the second dielectric layer 210 is a different material than the first dielectric layer 208.

According to embodiments of the present invention, a height, or thickness, of the second dielectric layer 210 is generally less than a design height, or thickness, of the via level 204. Furthermore, the height of the via level 204 is equal to a height of any conventional via level. For example, the via level 104 can range from approximately 1 nm to approximately 10 nm; however, other thicknesses are explicitly contemplated. Additionally, according to at least one embodiment, the relative height of the second dielectric layer 210 is approximately 30% to 40% of the total height of the via level 204.

Referring now to FIG. 13, the structure 200 is shown after forming a first pedestal 214 in accordance with an embodiment of the present invention.

An etching technique is applied to generally remove portions of the via level 204 according to known techniques. Specifically, a first mask 212 is formed directly on top of the second dielectric layer 210 and exposed portions of the second dielectric layer 110 are removed selective to the first mask 212, as shown. A suitable directional etching technique is used to etch exposed portions of the via level 104 and expose topmost surfaces of the first dielectric layer 108 and the conductive lines 106. In all cases, it is critical that topmost surfaces of the conductive lines 106 are exposed during etching, as illustrated. Doing so is critical to the function of the vertical antifuse structures disclosed herein, and which is described in greater detail below.

In some embodiments, the first mask 212 may include an oxide such as silicon oxide (SiO), a nitride such as silicon nitride (SiN), an oxynitride such as silicon oxynitride (SiON), combinations thereof, etc. In some embodiments, the mask 112 is a silicon nitride such as Si₃N₄.

The object of this directional etching technique is to form the first pedestal 214 generally arranged above the single conductive line 206, as illustrated. Also as illustrated, etching must expose at least portions of the top surfaces of the single conductive line 206. Suitable directional etching techniques may include, but are not limited to: reactive ion etching (RIE), ion beam etching, plasma etching, or laser ablation. In an embodiment, a RIE technique using, for example, with or without including argon ion species, may be used to remove portions of the via level 204, and more specifically to remove portions of the second dielectric layer 210.

Despite only a single first pedestal 214 is illustrated in FIG. 12, embodiments of the present invention explicitly contemplate configurations of the structure 200 which include multiple first pedestals 214 arranged above multiple conductive lines 206 respectively. In such embodiments, the first pedestals 214 are located or positioned in regions intended for the vertical antifuse structures described herein.

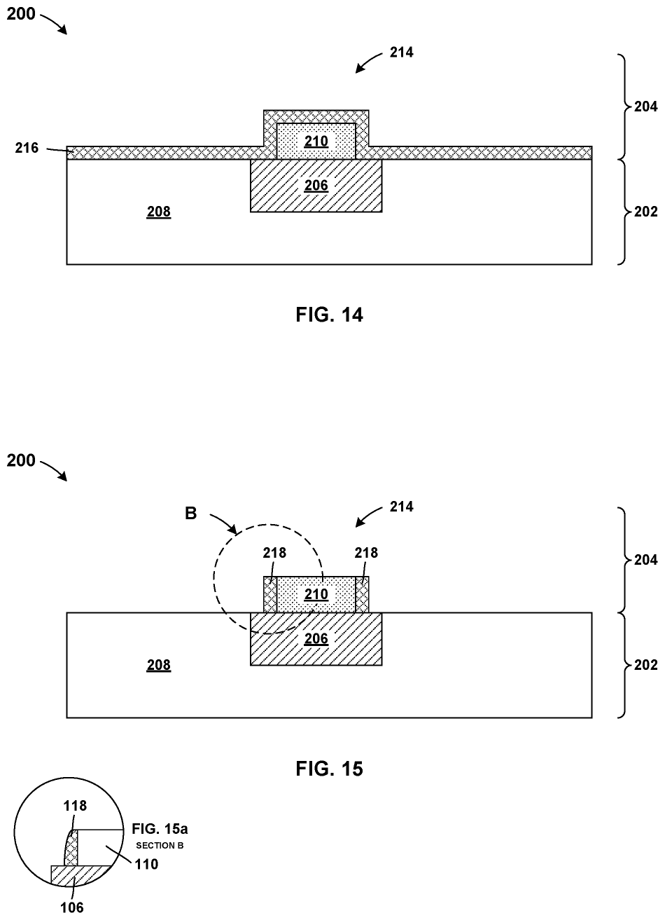

Referring now to FIG. 14, the structure 200 is shown after forming a first conductive layer 216 in accordance with an embodiment of the present invention.

After removing the first mask 212, the first conductive layer 216 is conformally deposited on exposed surfaces of the structure 200 according to known techniques. As used herein, “conformal” it is meant that a material layer has a continuous thickness, or substantially continuous thickness. For example, a continuous thickness generally means a first thickness as measured from a bottom surface to a topmost surface that is the same as a second thickness as measured from an inner sidewall surface to an outer sidewall surface.

According to embodiments of the present invention, the first conductive layer 216 may include any suitable conductive material capable of conducting sufficient current of any typical semiconductor circuit having a vertical antifuse structure. In an embodiment, the first conductive layer 216 may include tantalum nitride, titanium nitride, ruthenium, tungsten nitride, or some combination thereof. In at least one embodiment, the first conductive layer 216 may have a thickness, ranging from about 2 nm to about 30 nm, with 10 nm being most typical. Typically, the first conductive layer 216 may include a single layer; however, in other embodiments, it may include multiple layers of different conductive materials.

Since topmost surfaces of the conductive lines 206 are exposed during etching in a prior stage, the first conductive layer 216 will directly contact topmost surfaces of the conductive lines 206. It is critical to the function of the vertical antifuse structures described herein.

Referring now to FIGS. 15 and 15a, the structure 200 is shown after removing portions of the first conductive layer 216 to create a first metal sidewall spacer 218 in accordance with an embodiment of the present invention.

An anisotropic etch is used to remove portions of the first conductive layer 216 according to known techniques. Specifically, the anisotropic etch is used to remove portions of the first conductive layer 216 from horizontal surfaces of the structure 200 while leaving it on the sidewall of the first pedestal 214 and thereby forming the first metal sidewall spacer 218. Said differently, after etching the first metal sidewall spacer 218 remains on all sides of the first pedestal 214 and effectively surrounds the first pedestal 214. It is noted, the first pedestal 214 and the first metal sidewall spacer 218 may have similar alternated configurations as described above with reference to FIGS. 9, 10, and 11. Although, the metal sidewall spacer 218 does not function as a spacer as is understood persons having ordinary skill in the art, it is referred to as such due the processing techniques used to achieve the first metal sidewall spacer 218 mirror those used to create conventional dielectric sidewall spacers. According to all embodiments of the present invention, the first metal sidewall spacer 218 may also be referred to generally as a vertical conductor, a fuse conductor, or some combination thereof. More specifically, a bottommost surface of the first metal sidewall spacer 218 directly contacts a topmost surface the conductive line 206 and the sidewall of the first pedestal 214, as illustrated. In a preferred embodiment, an entirety of the bottommost surface of the first metal sidewall spacer 218 directly contacts a topmost surface of the conductive line 206.

In an embodiment, the first metal sidewall spacer 218 will be the same conductive material as the first conductive layer 216 described above. Also, like the first conductive layer 216 described above, the first metal sidewall spacer 218 may have a horizontal or lateral width, or thickness, similar to the thickness of the first conductive layer 216; however, etching may reduce the final thickness by about 10 percent. Further, sidewalls of the first metal sidewall spacer 218 may have a slightly rounded profile as a result of etching, as illustrated in FIG. 15a.

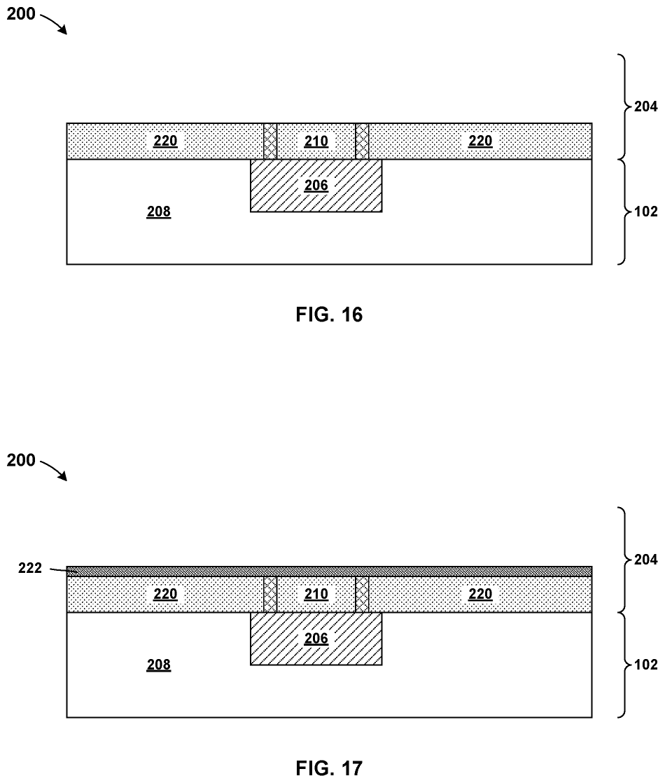

Referring now to FIG. 16, the structure 200 is shown after forming a third dielectric layer 220 in accordance with an embodiment of the present invention.

The third dielectric layer 220 is blanket deposited directly on exposed surfaces of the structure 200 according to known techniques. For purposes of the present description, the third dielectric layer 220 is the same, or substantially similar, as the second dielectric layer 210 previously described. In an alternate embodiment, the third dielectric layer 220 is a different material than the second dielectric layer 210.

After deposition, a planarization technique such as, for example, chemical mechanical planarization (CMP) and/or grinding is applied to remove excess material according to known techniques. After polishing the uppermost surfaces of the third dielectric layer 220 are flush, or substantially flush, with an uppermost surface of the second dielectric layer 210 and the first metal sidewall spacer 218.

Referring now to FIG. 17, the structure 200 is shown after forming a fuse dielectric 222 in accordance with an embodiment of the present invention.

The fuse dielectric 222 is blanket deposited directly on exposed surfaces of the structure 200 according to known techniques. It is critical to the present invention that the fuse dielectric 222 is different than either the second dielectric layer 210, the third dielectric layer 220, or both. More specifically, the fuse dielectric 222 is a dielectric material carefully selected for its dielectric breakdown properties. For example, according to embodiments of the present invention, the fuse dielectric 222 has a dielectric breakdown voltage less than the surrounding dielectrics. Dielectric breakdown is the failure of an insulating material to prevent the flow of current under an applied electrical stress. The breakdown voltage is the voltage at which the failure occurs, and the material is no longer electrically insulating.

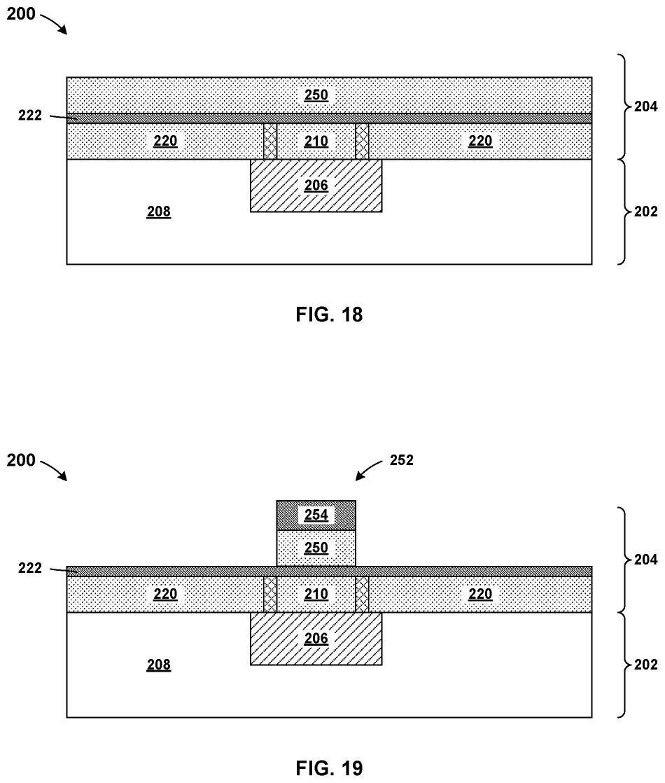

Referring now to FIG. 18, the structure 200 is shown after forming a fourth dielectric layer 250 in accordance with an embodiment of the present invention.

The fourth dielectric layer 250 is blanket deposited directly on exposed surfaces of the structure 200 according to known techniques. Specifically, the fourth dielectric layer 250 is deposited directly on top of the fuse dielectric 222. For purposes of the present description, the fourth dielectric layer 224 is the same, or substantially similar, as the second dielectric layer 210 and the third dielectric layer 220, previously described. In an alternate embodiment, the fourth dielectric layer 224 is a different material than the second dielectric layer 210, the third dielectric layer 220, or both.

According to embodiments of the present invention, a height, or thickness, of the fourth dielectric layer 250 is generally less than a design height, or thickness, of the via level 104. Additionally, according to at least one embodiment, the relative height of the fourth dielectric layer 250 is approximately 30% to 40% of the total height of the via level 104.

Referring now to FIG. 19, the structure 200 is shown after forming a second pedestal 252 in accordance with an embodiment of the present invention.

An etching technique is applied to generally remove portions of the via level 204 according to known techniques. Specifically, a second mask 254 is formed directly on top of the fourth dielectric layer 250 and exposed portions of the fourth dielectric layer 250 are removed selective to the second mask 254, as shown. A suitable directional etching technique is used to etch exposed portions of the via level 104 and expose topmost surfaces of the fuse dielectric 222.

In some embodiments, the second mask 254 may include an oxide such as silicon oxide (SiO), a nitride such as silicon nitride (SiN), an oxynitride such as silicon oxynitride (SiON), combinations thereof, etc. In some embodiments, the second mask 254 is a silicon nitride such as Si₃N₄.

The object of this directional etching technique is to form the second pedestal 252 generally arranged above and vertically aligned with the first pedestal 214, as illustrated. Also as illustrated, etching must expose at least portions of the fuse dielectric 222 directly above topmost surfaces of the first metal sidewall spacer 218. Suitable directional etching techniques may include, but are not limited to: reactive ion etching (RIE), ion beam etching, plasma etching, or laser ablation. In an embodiment, a RIE technique using, for example, with or without including argon ion species, may be used to remove portions of the via level 204, and more specifically to remove portions of the fourth dielectric layer 250.

Despite only a single second pedestal 252 is illustrated in FIG. 19, embodiments of the present invention explicitly contemplate configurations of the structure 200 which include multiple second pedestals 252 arranged above multiple first pedestals 214 respectively. In such embodiments, the first and second pedestals 214, 252 are located or positioned in regions intended for the vertical antifuse structures described herein.

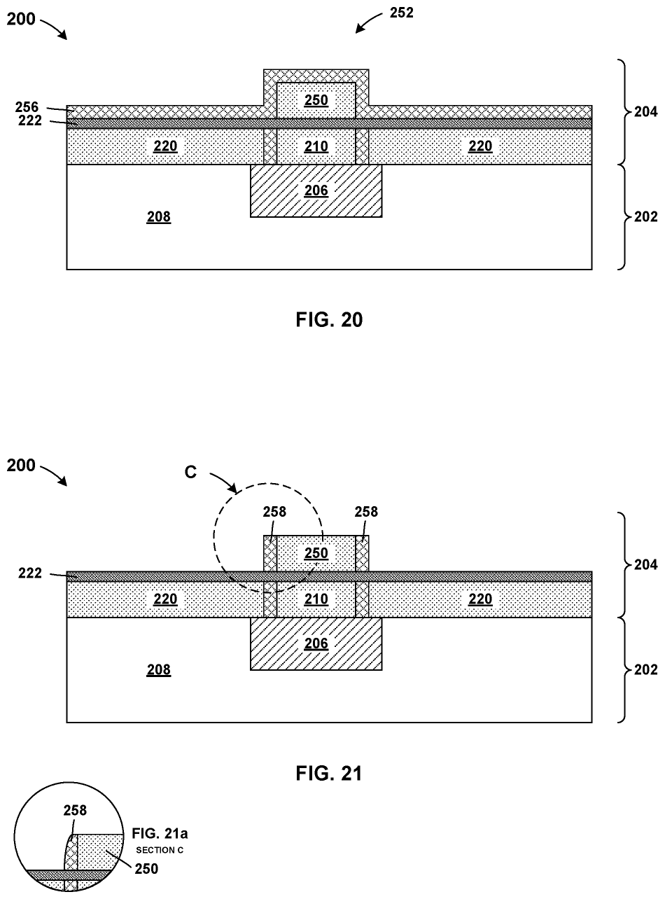

Referring now to FIG. 20, the structure 200 is shown after forming a second conductive layer 256 in accordance with an embodiment of the present invention.

After removing the second mask 254, the second conductive layer 256 is conformally deposited on exposed surfaces of the structure 200 according to known techniques. According to embodiments of the present invention, the second conductive layer 256 may include any suitable conductive material capable of conducting sufficient current of any typical semiconductor circuit having a vertical antifuse structure. In an embodiment, the second conductive layer 256 may include tantalum nitride, titanium nitride, ruthenium, tungsten nitride, or some combination thereof. In at least one embodiment, the second conductive layer 256 may have a thickness, ranging from about 2 nm to about 30 nm, with 10 nm being most typical. Typically, the second conductive layer 256 may include a single layer; however, in other embodiments, it may include multiple layers of different conductive materials. Since topmost surfaces of the fuse dielectric 222 are exposed during etching in a prior stage, the second conductive layer 256 will directly contact topmost surfaces of the fuse dielectric 222.

Referring now to FIGS. 21 and 21a, the structure 200 is shown after removing portions of the second conductive layer 256 to create a second metal sidewall spacer 258 in accordance with an embodiment of the present invention.

An anisotropic etch is used to remove portions of the second conductive layer 256 according to known techniques. Specifically, the anisotropic etch is used to remove portions of the second conductive layer 256 from horizontal surfaces of the structure 200 while leaving it on the sidewall of the second pedestal 252 and thereby forming the second metal sidewall spacer 258. Said differently, after etching the second metal sidewall spacer 258 remains on all sides of the second pedestal 252 and effectively surrounds the second pedestal 252. It is noted, the second pedestal 252 and the second metal sidewall spacer 258 may have similar alternated configurations as described above with reference to FIGS. 9, 10, and 11. Although, the second metal sidewall spacer 258 does not function as a spacer as is understood persons having ordinary skill in the art, it is referred to as such due the processing techniques used to achieve the second metal sidewall spacer 258 mirror those used to create conventional dielectric sidewall spacers. According to all embodiments of the present invention, the second metal sidewall spacer 258 may also be referred to generally as a vertical conductor, a fuse conductor, or some combination thereof. More specifically, a bottommost surface of the second metal sidewall spacer 258 directly contacts a topmost surface the fuse dielectric 222 and the sidewall of the second pedestal 252, as illustrated.

In an embodiment, the second metal sidewall spacer 258 will be the same conductive material as the second conductive layer 256 described above. Also, like the second conductive layer 256 described above, the second metal sidewall spacer 258 may have a horizontal or lateral width, or thickness, similar to the thickness of the second conductive layer 256; however, etching may reduce the final thickness by about 10 percent. Further, sidewalls of the second metal sidewall spacer 258 may have a slightly rounded profile as a result of etching, as illustrated in FIG. 21a.

In all cases, it is critical that the first metal sidewall spacer 218 be generally vertically aligned with the second metal sidewall spacer 258. Doing so is critical to the function of the vertical antifuse structures disclosed herein, and which is described in greater detail below. As such, misalignment between the first metal sidewall spacer 218 and the second metal sidewall spacer 258 may detrimentally affect function of the vertical antifuse structures disclosed herein. One method to reduce the negative effects of misalignment includes reducing the lateral size of the second pedestal 252 and increasing the thickness of the second conductive layer 256. In such cases, the second metal sidewall spacer 258 would be laterally wider than the first metal sidewall spacer 218. In such cases, the first metal sidewall spacer 218 may be vertically misaligned from the second metal sidewall spacer 258 and remain generally vertically aligned with one another.

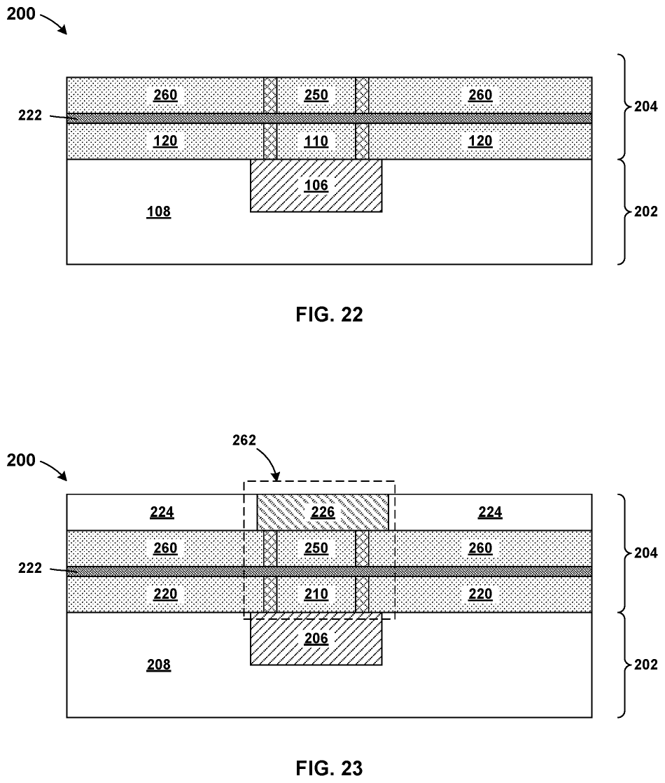

Referring now to FIG. 22, the structure 200 is shown after forming a fifth dielectric layer 260 in accordance with an embodiment of the present invention.

The fifth dielectric layer 260 is blanket deposited directly on exposed surfaces of the structure 200 according to known techniques. For purposes of the present description, the fifth dielectric layer 260 is the same, or substantially similar, as the fourth dielectric layer 250 previously described. In an alternate embodiment, the fifth dielectric layer 260 is a different material than the fourth dielectric layer 250.

After deposition, a planarization technique such as, for example, chemical mechanical planarization (CMP) and/or grinding is applied to remove excess material according to known techniques. After polishing the uppermost surfaces of the fifth dielectric layer 260 are flush, or substantially flush, with an uppermost surface of the fourth dielectric layer 250 and the second metal sidewall spacer 258.

Referring now to FIG. 23, the structure 200 is shown after forming a sixth dielectric layer 224 and a conductive element 226 in accordance with an embodiment of the present invention.

The sixth dielectric layer 224 is blanket deposited directly on exposed surfaces of the structure 200 according to known techniques. For purposes of the present description, the sixth dielectric layer 224 is the same, or substantially similar, as the first dielectric layer 208, the second dielectric layer 210, the third dielectric layer 220, the fourth dielectric layer 250, or the fifth dielectric layer 260 previously described. In an alternate embodiment, the sixth dielectric layer 224 is a different material than any of the first dielectric layer 208, the second dielectric layer 210, the third dielectric layer 220, the fourth dielectric layer 250, or the fifth dielectric layer 260.

Next, the conductive element 226 is formed in the sixth dielectric layer 224 according to known techniques. For example, according to typical damascene techniques, a trench is formed in the sixth dielectric layer 224 and then subsequently filled with a conductive material thereby forming the conductive element 226. According to disclosed embodiments, the conductive element 226 can be a metal line or via. Additionally, the vertical antifuse structure, made of the first metal sidewall spacer 218, the fuse dielectric 222, and the second metal sidewall spacer 258, is arranged in the via level 104 and functions to provide electrical connections between two successive metal levels, for example, the conductive line 206 and the conductive element 226. Although the conductive element 226 is described and disclosed as being part of the via level 204, the conductive element 226 may alternatively be part of a successive metal level above the via level 204.

As such, a cumulative height, or thickness, of the first metal sidewall spacer 218, the fuse dielectric 222, the second metal sidewall spacer 258 and the conductive element 226 is generally equal to a design height, or thickness, of the via level 104.

After deposition, a planarization technique such as, for example, chemical mechanical planarization (CMP) and/or grinding is applied to remove excess material according to known techniques. After polishing topmost surfaces of the sixth dielectric layer 224 are flush, or substantially flush, with a topmost surface of the conductive element 226, as illustrated.

Finally, for purposes of the present description the first metal sidewall spacer 218, the fuse dielectric 222, the second metal sidewall spacer 258 together form a vertical antifuse structure 262. Further, embodiments disclosed herein explicitly contemplate multiple vertical antifuse structures 262.

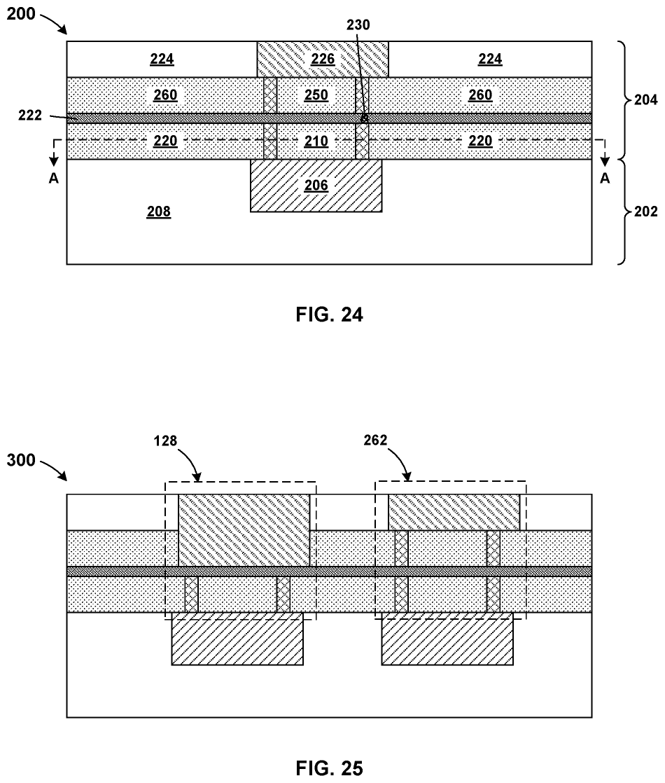

Referring now to FIG. 24, the structure 100 is shown after programming the vertical antifuse structure 262 in accordance with an embodiment of the present invention.

The relatively small distance between the first metal sidewall spacer 218 and the second metal sidewall spacer 258, coupled with the existence of the fuse dielectric 122 together create a “weak point” prone to electromigration. More specifically, electromigration during fuse programing creates a conductive link 230 between the first metal sidewall spacer 218 and the second metal sidewall spacer 258, as illustrated. The vertical antifuse structure 262 can be programmed by applying a programming voltage to one of the first metal sidewall spacer 218 or the second metal sidewall spacer 258 and grounding the other. In the context of the present invention, either the programming voltage or the ground may be applied to either of the first metal sidewall spacer 218 or the second metal sidewall spacer 258, and vice versa. According to the illustrated embodiment, the programming voltage and/or the ground may be applied to the first metal sidewall spacer 218 via the conductive line 106, and the programming voltage and/or the ground may be applied to the second metal sidewall spacer 258 via the conductive element 226. Persons having ordinary skill in the art understand the structure 200 disclosed herein will be part of a larger integrated circuit and include additional metal layers, wiring, traces, vias which may also be involved in programming.

The programming voltage, which should be equal to or greater than the breakdown voltage of the fuse dielectric 222 may range from about 1 V to about 10 V, and have a current ranging from about 2 mA to about 10 mA. As a result, conductive material from either the first metal sidewall spacer 218, the second metal sidewall spacer 258, or both, will migrate, or jump, through the fuse dielectric 222, as illustrated. Such migration of conductive material forms the conductive link 230 between the first metal sidewall spacer 218 and the first metal sidewall spacer 258, and thereby forms an electrical connection, for example the conductive link 230.

Although not critical, the conductive link 230 may have a lateral width or thickness ranging from about 1 nm to about 10 nm and ranges there between. The length of the conductive link 230 is approximately equal to a relative thickness of the fuse dielectric 222. In the present embodiments, the breakdown distance, or thickness of the fuse dielectric 222, is substantially equal to a vertical distance between the topmost surface of the first metal sidewall spacer 218 and the bottommost surface of the second metal sidewall spacer 258. Both the thickness of the fuse dielectric 222 and the material of the fuse dielectric 222 will affect how much programming current is required and how long it takes to program the vertical antifuse structure 262 or form the conductive link 230.

With continued reference to FIG. 24, although only a single conductive link 230 is depicted in the figures, programming may result in multiple conductive links 230 of varying sizes. Additionally, the one or more conductive links 230 may form anywhere along the corresponding surfaces of the first and second metal sidewall spacers 218, 258. As previously mentioned, programming of the vertical antifuse structure 262 is primarily dependent on the thickness of the fuse dielectric 222 and the material of the fuse dielectric 222; however, the lateral thickness of either the first metal sidewall spacer 218 or the second metal sidewall spacer 258 can also affect programing.

Referring now to FIG. 25 a demonstrative illustration of a structure 300 is shown during an intermediate step of a method of fabricating a vertical antifuse structure according to an alternative embodiment of the invention.

According to the embodiments disclosed herein, the structure 300 includes multiple vertical antifuse structures having different configurations, for example at least one antifuse configuration based on the vertical antifuse structure 128 and at least one antifuse configuration based on the vertical antifuse structure 262. Unique to the present embodiment, the multiple vertical antifuse structures 128, 262 share the same fuse dielectric. In accordance with embodiments disclosed herein, each of the vertical antifuse structures 128, 262 have different programming characteristics despite sharing the same fuse dielectric.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A vertical antifuse structure comprising:
a metal sidewall spacer arranged on a vertical sidewall of a dielectric pedestal;
a fuse dielectric layer on top of the dielectric pedestal; and
a conductive element on top of the fuse dielectric layer and directly above the metal sidewall spacer.

2. The semiconductor structure according to claim 1, further comprising:
a conductive line immediately below and directly contacting a bottommost surface of the metal sidewall spacer.

3. The semiconductor structure according to claim 2, wherein an entirety of a bottommost surface of the metal sidewall spacer directly contacts a topmost surface of the conductive line.

4. The semiconductor structure according to claim 1, wherein the metal sidewall spacer surrounds the dielectric pedestal on all sides.

5. The semiconductor structure according to claim 1, wherein a vertical distance between a topmost surface of the metal sidewall spacer and a bottommost surface of the conductive element is equal to a thickness of the fuse dielectric layer.

6. The semiconductor structure according to claim 1, wherein the conductive element further comprises another metal sidewall spacer surrounding another dielectric pedestal, wherein a topmost surface of the fuse dielectric layer directly contacts a bottommost surface of the another metal sidewall spacer.

7. The semiconductor structure according to claim 1, further comprising:
a conductive link in direct contact with and extending between a topmost surface of the metal sidewall spacer and a bottommost surface of the conductive element through the fuse dielectric layer.

8. A vertical antifuse structure comprising:
a metal sidewall spacer arranged on a vertical sidewall of a dielectric pedestal;
a conductive element directly above the metal sidewall spacer; and
a fuse dielectric layer between and separating the metal sidewall spacer from the conductive element.

9. The semiconductor structure according to claim 8, further comprising:
a conductive line immediately below and directly contacting a bottommost surface of the metal sidewall spacer.

10. The semiconductor structure according to claim 9, wherein an entirety of a bottommost surface of the metal sidewall spacer directly contacts a topmost surface of the conductive line.

11. The semiconductor structure according to claim 8, wherein the metal sidewall spacer surrounds the dielectric pedestal on all sides.

12. The semiconductor structure according to claim 8, wherein a vertical distance between a topmost surface of the metal sidewall spacer and a bottommost surface of the conductive element is equal to a thickness of the fuse dielectric layer.

13. The semiconductor structure according to claim 8, wherein the conductive element further comprises another metal sidewall spacer surrounding another dielectric pedestal, wherein a topmost surface of the fuse dielectric layer directly contacts a bottommost surface of the another metal sidewall spacer.

14. The semiconductor structure according to claim 8, further comprising:
a conductive link in direct contact with and extending between a topmost surface of the metal sidewall spacer and a bottommost surface of the conductive element through the fuse dielectric layer.

15. A vertical antifuse structure comprising:
a first metal sidewall spacer disposed on a vertical sidewall of a first dielectric pedestal;
a first conductive element directly above the first metal sidewall spacer;
a second metal sidewall spacer disposed on a vertical sidewall of a second dielectric pedestal;
a second conductive element directly above the second metal sidewall spacer; and
a fuse dielectric layer, the fuse dielectric layer arranged between and separating the first metal sidewall spacer from the first conductive element, and the fuse dielectric layer arranged between and separating the second metal sidewall spacer from the second conductive element.

16. The semiconductor structure according to claim 15, further comprising:
a first conductive line immediately below and directly contacting a bottommost surface of the first metal sidewall spacer; and
a second conductive line immediately below and directly contacting a bottommost surface of the second metal sidewall spacer.

17. The semiconductor structure according to claim 16, wherein an entirety of a bottommost surface of the first metal sidewall spacer directly contacts a topmost surface of the first conductive line, and wherein an entirety of a bottommost surface of the second metal sidewall spacer directly contacts a topmost surface of the second conductive line.

18. The semiconductor structure according to claim 15, wherein the first metal sidewall spacer surrounds the first dielectric pedestal on all sides, and wherein the second metal sidewall spacer surrounds the second dielectric pedestal on all sides.

19. The semiconductor structure according to claim 15, wherein a vertical distance between a topmost surface of the first metal sidewall spacer and a bottommost surface of the first conductive element is equal to a thickness of the fuse dielectric layer, and wherein a vertical distance between a topmost surface of the second metal sidewall spacer and a bottommost surface of the second conductive element is equal to the thickness of the fuse dielectric layer.

20. The semiconductor structure according to claim 15, wherein the second conductive element further comprises a third metal sidewall spacer surrounding a third dielectric pedestal, wherein a topmost surface of the fuse dielectric layer directly contacts a bottommost surface of the third metal sidewall spacer.
